(19) United States
(12) Patent Application Publication
(10) Pub. No.: US 2014/0374068 A1
(43) Pub. Date: Dec. 25, 2014

(54) METHOD AND APPARATUS FOR DISSIPATING HEAT FROM A LIQUID-IMMERSED TRANSFORMER

(71) Applicant: Qing Gan Zeng, North Vancouver (CA)

(72) Inventor: Qing Gan Zeng, North Vancouver (CA)

(21) Appl. No.: 14/041,832

(22) Filed: Sep. 30, 2013

(30) Foreign Application Priority Data
Jun. 21, 2013 (CN) 201310248814.2

(51) Int. Cl. H05K 7/20

(52) U.S. Cl. CPC H05K 7/20236
USPC 165/104.33

(57) ABSTRACT

An apparatus for dissipating heat from a liquid-immersed electric transformer comprises a main tank for containing the transformer and a radiator comprising one or more radiating elements positioned on a top surface of the main tank. The one or more radiating elements are each fluidly coupled to the main tank through one or more connecting ports disposed between the top surface of the main tank and a bottom end of each radiating element. Heat is transferred from the main tank to the radiator primarily via Rayleigh-Bénard convection and ultimately dissipated to ambient air from the radiator.

### TECHNICAL FIELD

Aspects of the present disclosure relate generally to methods for dissipating heat from a liquid-immersed electric transformer.

### BACKGROUND

A transformer generates heat during operation. This heat originates from various sources including, but not limited to, the reversing of the magnetic field permeating through the core of the transformer (“core loss”) and the flow of current through winding conductors in the transformer (“winding loss”). To ensure safe and effective functioning of the transformer, heat must be properly dissipated.

Various transformer designs and methods have been used to dissipate heat generated by a transformer. In one example, a transformer, as depicted by the intersecting circles in FIG. 1, is placed in the main tank 1 of an apparatus and immersed in a liquid (not numbered), such as an oil, that functions to insulate and conduct heat away from the transformer. Each radiator 3, in the form of a pipe, is connected to the main tank 1 in at least two locations: near the top surface of the main tank 1 (an “entry port”), and near the base of the main tank 1 (an “exit port”). The cavity of each radiator 3 is filled with the same liquid in which the transformer is immersed, and is in fluid communication with the cavity of the main tank 1. Heat that is generated by the operation of the transformer is transferred from the transformer to the liquid. Heated liquid rises and enters each radiator 3 at the entry. In each radiator 3, heat from the liquid is then transferred to the walls of the radiator and ultimately dissipated to ambient surroundings. The cooled liquid sinks and re-enters the cavity of the main tank 1 through the exit port.

Further referring to FIG. 1, a liquid storage tank 2 is positioned at the top of the main tank 1, and that is in fluid communication with the cavity of the main tank 1. The height of the liquid surface inside the storage tank 2 is above the path of liquid circulation between the main tank 1 and the radiators 3. Liquid storage tanks are often incorporated into the design of transformer systems to lessen mechanical stress on the transformer tank and one or more radiators caused by the expansion and contraction of the liquid during transformer operation.

In another example as depicted in FIG. 2, the inner cavity of a radiator 3 is in fluid communication with the main tank 1 of a transformer apparatus through connecting pipes (not numbered). Heated liquid from the main tank 1 enters the radiator 3 though the entry port located at the top surface of the main tank 1. The heated liquid flows into the radiator 3 and heat is dissipated through the walls of the radiator 3 to the ambient surroundings. The cooled liquid sinks and re-enters the cavity of the transformer tank 1 from the radiator 3 through a connecting pipe exit port that is connected to a location near the base of the main tank 1. Additionally, a liquid storage tank 2 is in fluid communication with the cavity of the transformer tank 1, and the height of the liquid surface inside the oil storage tank 2 is above the path of liquid circulation between the transformer tank 1 and the radiator 3.

Radiators in the prior art are generally connected to the main tank of transformer apparatus at two points: a liquid entry port and a liquid exit port. In addition, prior art designs and methods principally dissipate heat from a transformer using the principles of natural liquid circulation. In natural liquid circulation, a liquid experiences “volume flow”; that is, the displacement of a volume of liquid may be measured by a positive-displacement flow meter. Generally, designs that facilitate natural liquid circulation are spatially inefficient because the radiators, as shown in FIGS. 1 and 2 for example, are installed on the sides of the main tank of the transformer. In other words, the installation of radiators on the sides of a transformer tank occupies floor area that could otherwise be utilized for other applications. In addition, in order for natural liquid circulation to occur, a temperature gradient must exist in the radiator wherein the surfaces of the radiator proximate to the entry port of the radiator are hotter than the surfaces proximate to the exit port of the radiator. The colder surfaces of the radiator proximate to the exit port have a lower heat dissipation capacity than the hotter surfaces of the radiator proximate to the entry port, and this occurrence negatively affects the rate of heat dissipation in these prior art designs and methods.

### SUMMARY

Aspects of the present disclosure relate generally to dissipating heat from liquid-immersed electric transformers.

According to one aspect of the disclosure, there is an apparatus for dissipating heat from a liquid-immersed electric transformer comprising a radiator with one or more radiating elements. The one or more elements are disposed vertically and parallel to each other above a main tank of the transformer. The inner cavities of the one or more elements of the radiator are fluidly coupled to the main tank through a connecting port located at a bottom end of the one or more radiating elements. The main tank is fully filled with a liquid that functions to insulate and conduct heat away from the transformer, and the liquid is filled to a pre-determined height in the radiator. The heat generated from at least the core and winding losses of the transformer is absorbed by the liquid in the main tank, and dissipated to the liquid in the radiator through each connecting port in between each radiating element and the main tank. The heat from liquid in the radiator is then dissipated to ambient air.

According to another aspect of the disclosure, there is an apparatus for dissipating heat from a liquid-immersed electric transformer comprising a radiator with one or more radiating elements. The one or more elements are disposed vertically and parallel to each other above a main tank of the transformer. The inner cavities of the elements of the radiator are fluidly coupled to the main tank through a connecting port located at a bottom end of each radiating element. The main tank and radiator are fully filled with a liquid that functions to insulate and conduct heat away from the transformer. The heat generated from at least the core and winding losses of the transformer is absorbed by the liquid in the main tank, and dissipated to the liquid in each radiating element through each connecting port in between each radiating element and the main tank. The heat from liquid in the radiator is then dissipated to ambient air. According to this aspect of the disclosure, the main tank has a means for expanding in the vertical direction and adjusting the total volume of liquid storage space to accommodate any increase in volume of the liquid during operation of the transformer.

According to another aspect of the disclosure, there is a method of dissipating heat from a liquid-immersed electric transformer, the method comprising using an apparatus to dissipate heat from the transformer.

This summary does not necessarily describe the entire scope of all aspects. Other aspects, features and advantages will be apparent to those of ordinary skill in the art upon review of the following description of specific embodiments.

### BRIEF DESCRIPTION OF THE DRAWINGS

In the accompanying drawings, which illustrate one or more exemplary embodiments:

FIG. 1 is a front view drawing of a prior art apparatus for dissipating heat from a transformer.

FIG. 2 is a front view drawing of another prior art apparatus for dissipating heat from a transformer.

FIG. 3 is a front view drawing of an apparatus for dissipating heat from a transformer using radiators, according to one embodiment.

FIG. 4 is a side view of one of the radiators in FIG. 3.

FIG. 5 is a cross-sectional view along section A-A of the radiator in FIG. 4.

FIG. 6 is a front view drawing of an apparatus for dissipating heat from a transformer wherein the transformer tank has means for expanding.

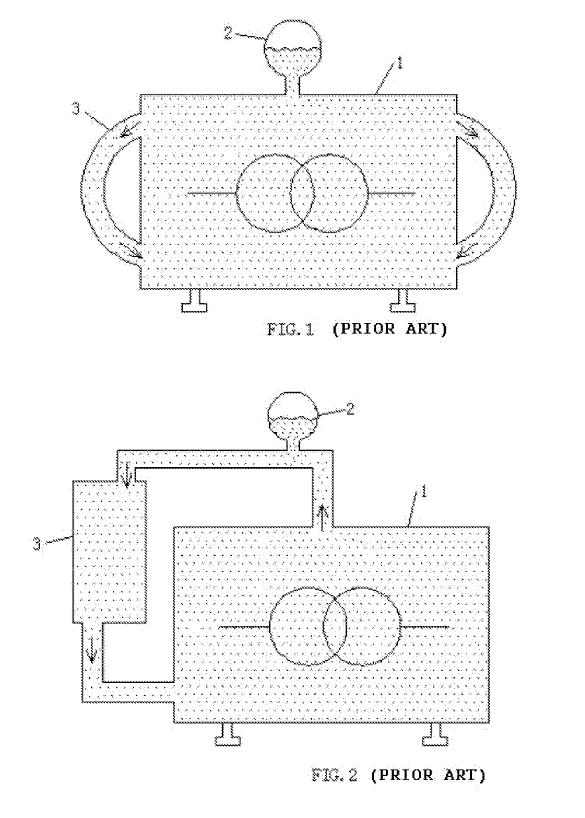

### DETAILED DESCRIPTION

Directional terms such as “upper”, “lower”, “bottom”, “top”, “right” and “left” provide relative reference only, and do not limit the embodiments of the present invention in any way. The plural and singular forms may be used interchangeably without limitation to the embodiments of the present invention in any way.

Rayleigh-Bénard convection was discovered in 1900. In this form of convection, a liquid is generally heated from below and heat is transferred from a hotter lower region to a colder upper region of the liquid. Regular patterns of convection cells, known as Bénard cells, develop when the temperature difference (ΔT) between the hotter lower and colder upper regions of the liquid exceeds a critical temperature threshold (ΔT_{c}). Rayleigh-Bénard convection is a form of sub-cooled boiling heat transfer. Sub-cooled boiling heat transfer is a heat transfer process where a surface (e.g. the surface of a winding of a transformer) is immersed in a liquid (e.g. an oil) and the temperature of the liquid remains below its saturation point (i.e. boiling point).

Embodiments of the present disclosure described herein relate to an apparatus for and method of dissipating heat from a liquid-immersed electric transformer using the principles of Rayleigh-Bénard convection and more generally sub-cooled boiling heat transfer. The embodiments of the present disclosure described herein do not require a liquid storage tank. Although the embodiments of the present disclosure undergo liquid turbulence owing to Rayleigh-Bénard convection, they do not however undergo natural liquid circulation, which is described as “volume flow” in the Background section, between its radiators and main tank. For clarity, “volume flow” is defined as fluid flow that can be measured by a positive-displacement flow meter.

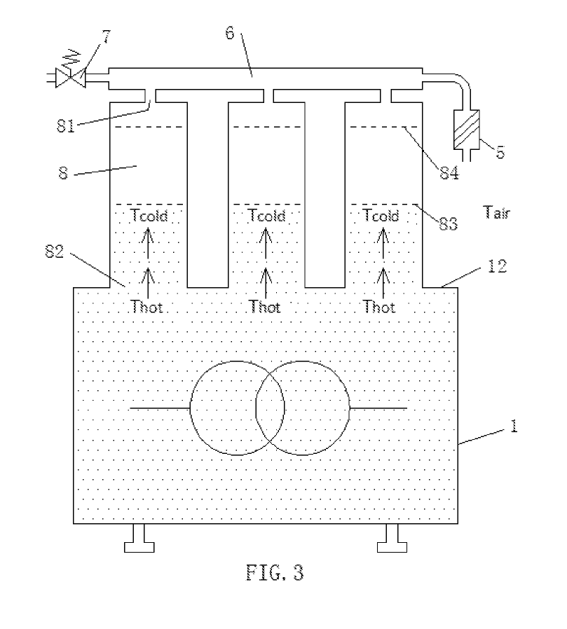

Referring to FIG. 3 and according to one embodiment of the present disclosure, there is an apparatus for and method of dissipating heat from a transformer. In this embodiment, the transformer (depicted by intersecting circles) is disposed in an apparatus that includes a main tank 1, a radiator (un-numbered) comprising one or more radiating elements 8, a gas collection tube 6, a damp-proof respirator 5, and a pressure release valve 7. Each radiating element 8 has a first end located at one or more connecting ports 82 between the top surface of main tank 1 and radiating element 8, and a second end located at one or more venting holes 81 disposed at the top of the radiating element 8. For clarity, the second end of each radiating element is not attached to the main tank 1. Each radiating element 8 of the radiator is fluidly coupled to the main tank through one or more connecting ports 82 extending through the top surface of the main tank and a bottom end of each of the one or more radiating elements. Radiating elements 8 may be, but are not limited to being, panels. The gas collection tube 6 is disposed on top of the radiator and fluidly coupled to the radiator. The gas collection tube 6 is connected to the damp-proof respirator 5 and pressure release valve 7. The damp proof respirator 5 provides a means of fluid communication between the gas collection tube 6 and external ambient air. Pressure release valve 7 is activated in the event of pressure build up (e.g. if heated air in the “head space” is not replaced with ambient air) within the apparatus or damp-proof respirator 5 malfunction. The apparatus may be constructed of a heat conducting material such as steel.

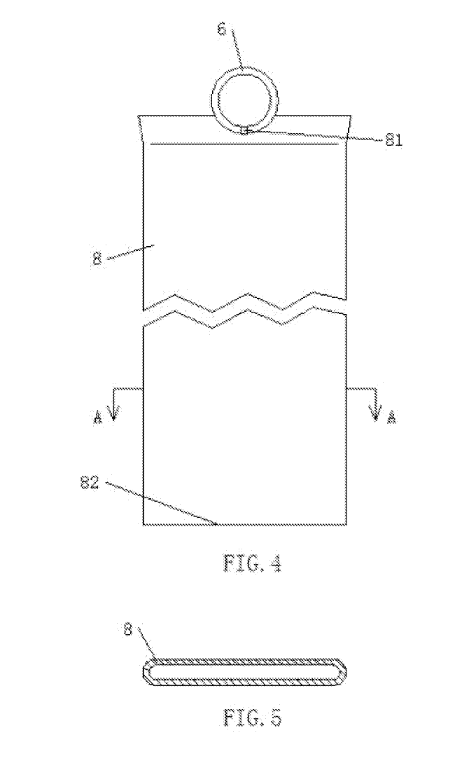

Referring to FIG. 3, the radiator comprises three radiating elements 8 of equal length disposed vertically, parallel to each other, and to the same height on top surface 12 of the main tank 1. In practice, any desired number of radiating elements may be disposed above the main tank. Connecting ports 82 are drilled into top surface 12. The bottom ends of radiating elements 8 are welded onto the external surface of top surface 12 and over the connecting ports 82. While more than one connecting port may provide fluid communication between each radiating element 8 and the main tank 1, only one connecting port 82 provides a means of fluid communication between each radiating element 8 and the main tank 1 in the embodiment illustrated in FIG. 3. Alternatively, a connecting tube (not shown) provides a means of fluid communication between each radiating element 8 and the main tank 1. In addition, venting holes 81 are drilled into the gas collection tube 6 and the top ends of the radiating elements 8 are welded onto the external surface of the gas collection tube 6 and over the venting holes 81. While more than one venting hole may provide fluid communication between each radiating element 8 and gas collection tube 6, only one venting hole 81 provides a means of fluid communication between each radiating element 8 and the gas collection tube 6 in the embodiment illustrated in FIG. 3. Alternatively, a venting tube (not shown) provides a means of fluid communication between each radiating element 8 and the gas collection tube 6. For clarity, while venting holes 81 are in fluid communication with the main tank 1, they are not directly attached to the main tank 1. Radiating element 8 may be of any shape. Referring to FIG. 5, which depicts a cross-sectional view across line A-A of the radiating element 8 depicted in FIG. 4, radiating element 8 may have an obround cross-sectional shape with a narrow width. In some embodiments, the volume of the cavity in each radiating element 8 is minimized to accommodate a plurality of radiating elements 8 that may be disposed vertically, parallel to each other, and to the same height on top of the main tank 1.

Prior to operation, the transformer is disposed within the main tank 1. A liquid that functions to insulate and conduct heat away from the transformer, such as transformer oil, is added into the main tank 1 through an injection valve (not shown) located on the main tank 1. An appropriate liquid generally has a Rayleigh-Bénard convection heat transfer coefficient between 5,000 and 45,000 W·m⁻²·K⁻¹. In addition, the heat transfer coefficient between wall and air is generally between 5 and 25 W·m⁻²·K⁻¹. A venting valve (not shown) is also opened to allow air within the apparatus to escape while the apparatus is filled with the liquid. The inner cavity of the main tank 1 is filled with the liquid, and the transformer is immersed in the liquid. The liquid is added to the transformer system until the inner cavity main tank 1 is fully filled, the liquid enters each radiating element 8 through its connecting port 82, and the liquid is filled to a pre-determined height 83 in the radiator such that during the operation of the transformer of a rated load, and depending on the thermal properties of the liquid during transformer operation, the liquid expands to a rated liquid height 84 in the radiator. The venting valve is closed when the liquid is filled to the pre-determined height 83. The rated liquid height 84 is the height of the liquid in the radiator at which heat is effectively dissipated from the apparatus. For safety reasons, the radiator has a height of at least the rated liquid height 84. The rated liquid height 84 will vary according to the radiator's volume and shape.

During the operation of the transformer, heat is generated from at least the core and winding losses of the transformer. This heat is initially transferred to the liquid in the main tank 1. The liquid in the main tank 1 increases in temperature until the temperature difference between liquid within main tank 1 and the liquid at the liquid/air interface of radiating elements 8 exceeds a critical temperature threshold (ΔT_{c}). At that point, the liquid in the radiating elements 8 undergo Rayleigh-Bénard convection. In other words, heat in the liquid of the main tank 1 is transferred to the liquid in the radiator through each connecting port disposed at the bottom of each radiating element 8 primarily by Rayleigh-Bénard convection or sub-cooled boiling heat transfer. For illustrative purposes, the arrows shown in FIG. 3 depict the ultimate direction of heat transfer in a transformer system. While heat may be dissipated through the walls of main tank 1, heat is primarily dissipated from the apparatus through the walls (i.e. heat dissipating surfaces) of each radiating element 8 to the ambient air. The damp-proof respirator 5 removes heated air in each radiating element 8 and the gas collection tube 6, and replaces it with ambient air. In the event of above normal-pressure building up within the apparatus, pressure release valve 7 is activated and built-up pressure within the apparatus is released.

According to another embodiment of the disclosure, there is an apparatus and method for dissipating heat from a transformer. In this embodiment, the transformer is disposed in an apparatus that includes the main tank, and a radiator comprising one or more radiating elements disposed vertically, parallel to each other, and to the same height on top of the main tank. Each radiating element has a first end located at one or more connecting ports between the main tank and radiating element, and a second end located at the top of the radiating element. For further clarity, the second end of the radiating element is not attached to the main tank. Each radiating element within the radiator is fluidly coupled to the main tank through one or more connecting ports extending through the top surface of the main tank and a bottom end of each of the one or more radiating elements. The radiating elements are of equal length disposed vertically, parallel to each other, and to the same height on top surface of the main tank. One or more venting holes or tubes are located at the top of each radiator element providing fluid communication between the radiating elements and ambient air. Alternatively, the venting holes or tubes may be sealed. In some embodiments, the volume of the cavity in each radiating element is minimized to potentially accommodate a plurality of radiating elements that may be disposed vertically and parallel to each other on top of the main tank.

During the operation of the transformer, heat is generated from at least the core and winding losses of the transformer. This heat is initially transferred to the liquid in the main tank. The liquid in the main tank increases in temperature until the temperature difference between liquid within the main tank and the liquid at the liquid/air interfaces of radiating elements 8 exceeds a critical temperature threshold (ΔT_{c}). At that point, the liquid in the radiating elements undergo Rayleigh-Bénard convection. In other words, heat in the liquid of the main tank is transferred to the liquid in the radiator through each connecting port disposed at the bottom of each radiating element 8 primarily by Rayleigh-Bénard convection or sub-cooled boiling heat transfer. While heat may be dissipated through the walls of main tank, heat is primarily dissipated from the apparatus through the walls (i.e. heat dissipating surfaces) of each radiating element 8 to the ambient air.

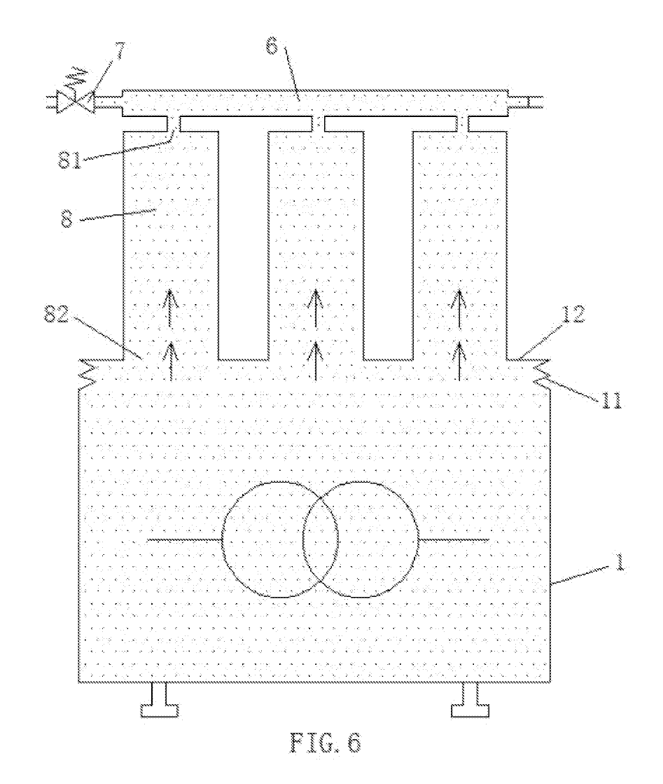

Referring to FIG. 6 and according to yet another embodiment of the present disclosure, there is an apparatus and method for dissipating heat from a transformer. In this embodiment, the transformer disposed in an apparatus that comprises a main tank 1 with a top surface 12, the transformer depicted by the intersecting circles in the main tank 1, a gas collection tube 6, and a radiator (un-numbered) comprising one or more radiating elements 8 (three radiating elements are depicted in FIG. 6) disposed vertically, parallel to each other, and to the same height on top surface 12 of the main tank 1. Each radiating element 8 has a first end located at one or more connecting ports 82 between the top surface of main tank 1 and radiating element 8, and a second end located at one or more venting holes 81 disposed at the top of the radiating element 8. Connecting ports 82 are drilled into top surface 12. The bottom ends of radiating elements 8 are welded onto the external surface of top surface 12 and over the connecting ports 82. While more than one connecting port may provide fluid communication between each radiating element 8 and the main tank 1, only one connecting port 82 provides a means of fluid communication between each radiating element 8 and the main tank 1 in the embodiment illustrated in FIG. 6. In addition, venting holes 81 are drilled into the gas collection tube 6 and the top ends of the radiating elements 8 are welded onto the external surface of the collection tube 6 and over the venting holes 81. The gas collection tube 6 is fluidly coupled to the radiator. While more than one venting hole may provide fluid communication between each radiating element 8 and gas collection tube 6, only one venting hole 81 provides a means of fluid communication between each radiating element 8 and the gas collection tube 6 in the embodiment illustrated in FIG. 6. For clarity, while venting holes 81 are in fluid communication with the main tank 1, they are not directly attached to the main tank 1. A pressure release valve 7 is also connected to the gas collection tube 6. Other than when the pressure release valve 7 is activated, the inner cavity of the gas collection tube 6 is not in communication with external ambient air. Additionally, the transformer apparatus contains a means 11 of expanding the volume of the main tank 1 and contracting the volume of the main tank 1 from an expanded state.

Prior to operation, a transformer, depicted by the un-numbered intersecting circles, is disposed within the main tank 1. A liquid, such as transformer oil, is added into the main tank 1 through an injection valve (not shown) on the main tank 1. A venting valve (not shown) is opened to allow air within the apparatus to escape while the apparatus is filled with the liquid. The liquid is added until the inner cavities of main tank 1, radiators 8, and collection tube 6 (i.e. the inner cavities of the entire apparatus) are fully filled with the liquid and the transformer is fluidly immersed, at which point, the venting valve is closed to prevent the liquid from escaping the apparatus.

During the operation of the transformer, heat is generated from at least the core and winding losses of the transformer. This heat is initially transferred to the liquid in the main tank 1. The liquid in the main tank 1 increases in temperature until the temperature difference between liquid in the main tank 1 and the liquid in the radiating elements 8 exceeds a critical temperature threshold (ΔT_{c}). At that point, the liquid in the radiating elements 8 undergo Rayleigh-Bénard convection. In other words, heat in the liquid of the main tank 1 is transferred to the liquid in the radiator through each connecting port disposed at the bottom of each radiating element 8 primarily by Rayleigh-Bénard convection or sub-cooled boiling heat transfer. While heat may be dissipated through the walls of the main tank 1, heat is primarily dissipated from the apparatus through the walls (i.e. heat dissipating surfaces) of each radiating element 8 to the ambient air. In the event of above normal-pressure building up within the apparatus, pressure release valve 7 is activated and built-up pressure within the apparatus is released from the apparatus.

During operation of the transformer, the liquid inside the transformer system thermally expands. To accommodate this expansion, the total volume of liquid storage space in the apparatus increases by way of expansion means 11 which causes the top surface 12, the radiator and the collection tube 6 to rise in the vertical direction. An example of expansion means 11 may be, but is not limited to being expansion joints. As heat is dissipated and the temperature of the liquid decreases, the top surface 12 lowers and the total volume of liquid storage space adjusts according to the volume of the liquid.

### EXAMPLE

The following example is an illustrative embodiment of the present disclosure and in no way limits any other embodiment of the present disclosure.

A transformer is disposed in a main tank of a heat dissipating apparatus. On the top surface of the main tank, there is a radiator with one radiating element disposed vertically and perpendicular to the top surface. An obround shaped connecting port with an internal width and length of 10 mm and 493 mm respectively is drilled into the top surface of the main tank. The radiator is constructed from a pre-fabricated steel sheet that has a thickness of 1 mm, and is shaped according to the dimensions and shape of the connecting port. That is to say, the inner cavity of the element has a width of 10 mm and a length of 493 mm. The bottom end of the element is then welded to the top surface of the main tank such that the connecting port provides a means of fluid communication between the radiator and the main tank. Because the thickness of the walls of the radiator is 1 mm, thermal resistance is assumed to be negligible.

For an apparatus comprising a radiator with one radiating element, the rated liquid height in the radiator may be calculated according to the following heat-balance equation:

H=(h_{B}·ΔT_{B}·d)/(hₐ·ΔT_{R}·2) (1)

where “H” is the rated liquid height in the radiator or the minimum height of the radiator panel needed to contain the liquid during transformer operation, “h_{B}” is the Rayleigh-Bénard convection heat transfer coefficient of the liquid, “ΔT_{B}” is the Rayleigh-Bénard convection temperature difference between the liquid in the main tank and the liquid at the liquid/air interface in the radiating elements, “d” is the width of the connecting port 82 between radiator panel and the main tank 1, “hₐ” is the heat transfer coefficient of the radiator between wall and ambient air, “ΔT_{R}” is the temperature difference between the liquid at the liquid/air interface in the element and ambient air, and 2 is the number of sides of a panel-radiator that effectively radiates heat.

In this example where the desired conditions of a transformer apparatus are such that “ΔT_{R}” is 45K, “hₐ” is 15 W·m⁻²·K⁻¹, “ΔT_{B}” is 10K, “h_{B}” is 20,000 W·m⁻²·K⁻¹ and width “d” of the connecting hole is 10 mm, an appropriate rated liquid height during transformer operation would be 1.48 m. Thus, the vertical height of the radiator would have to be equal to or greater than (for safety reasons) the rated liquid height.

It is contemplated that any part of any aspect or embodiment discussed in this specification can be implemented or combined with any part of any other aspect or embodiment discussed in this disclosure. While particular embodiments and examples have been described in the foregoing disclosure, it is understood that other embodiments are possible and are intended to be included herein. A person skilled in the art understands that modifications and amendments to the foregoing embodiments are possible. The claims of this disclosure should be given an interpretation that is consistent with the description as a whole, and not limited to any specific embodiment set forth in the disclosure.

1. An apparatus for dissipating heat from a liquid-immersed electric transformer, the apparatus comprising:
a main tank for containing the transformer; and
a radiator comprising one or more radiating elements, each of the radiating elements comprising first and second ends and standing vertically on a top surface of the main tank, and
wherein the first end of each of the radiating elements is attached to the top surface of the main tank and the second end of each of the radiating elements is detached from the main tank, and wherein a liquid extends into the radiating element from the main tank such that, when the apparatus is in use, heat enters the radiating elements via the liquid.

2. The apparatus according to claim 1, wherein the one or more radiating elements are panels extending to identical heights and disposed parallel to each other on top of the main tank.

3. The apparatus according to claim 2, wherein the one or more radiating elements are each fluidly coupled to a gas collection tube through one or more venting holes disposed between the gas collection tube and a top end of the radiating element.

4. The apparatus according to claim 3, wherein a pressure release valve is coupled to the gas collection tube.

5. The apparatus according to claim 3, wherein a damp-proof respirator is fluidly coupled to the gas collection tube.

6. The apparatus according to claim 1, wherein the main tank has a means for expanding and contracting.

7. The apparatus according to claim 1, wherein the main tank further comprises expansion joints that permit the main tank to vertically expand and contract.

8. A method for manufacturing an apparatus for dissipating heat from a liquid-immersed electric transformer that is contained within a main tank of the apparatus, the method comprising:
locating a radiator above a top surface of the main tank, the radiator comprising one or more radiating elements which are disposed vertically on the top surface of the main tank; and
connecting the one or more radiating elements to the main tank through one or more connecting ports extending through the top surface of the main tank and a bottom end of each of the one or more radiating elements; and
locating one or more venting holes on a top end of each of the one or more radiating elements; and
filling the main tank fully with a liquid to the connecting ports; and
filling the radiating elements above the connecting ports with the liquid to a height, and
wherein, when the transformer is in operation and the liquid in the main tank is being heated by the heat generated by the transformer, heat is transferred from the main tank to the one or more radiating elements through the one or more connecting ports primarily via Rayleigh-Bénard convection and ultimately dissipated to ambient air through walls of the one or more radiating elements.

9. A method according to claim 8, the method further comprising:
removing heated air from the one or more radiating elements; and
replacing the heated air with ambient air.

10. A method according to claim 8, wherein the height is pre-determined according to a rated load of the transformer and thermal properties of the liquid such that, during the operation of the transformer of a rated load, the liquid expands to a rated liquid height in the radiator.

11. A method according to claim 8, further comprising:
introducing to the main tank a means for expanding and contracting to accommodate an expansion of the liquid during the operation of the transformer; and
keeping open a venting valve at a top of the apparatus while the apparatus is filled with the liquid to allow air within the apparatus to escape through the venting valve; and
closing the venting valve after the apparatus has been fully filled with the liquid, and
wherein, when the transformer is in operation, a volume of the apparatus varies according to a volume of the liquid.
